(19) United States
(12) Patent Application Publication
(10) Pub. No.: US 2007/0272836 A1
(43) Pub. Date: Nov. 29, 2007

(54) Photoelectric conversion apparatus

(76) Inventors: Yoshihito Higashitsutsumi, Atsugi-shi (JP); Shinichiro Izawa, Atsugi-shi (JP); Kuniyuki Tani, Ogaki-shi (JP); Kazuhiko Suzuki, Ampachi-gun (JP); Yukiko Mishima, Motosu-shi (JP)

Correspondence Address: CANTOR COLBURN, LLP, 55 GRIFFIN ROAD SOUTH, BLOOMFIELD, CT, 06002, US

(21) Appl. No.: 11/804,181

(22) Filed: May 17, 2007

(30) Foreign Application Priority Data
May 17, 2006 (JP) 2006-137270

(51) Int. Cl. G01J 3/50; H01J 40/14

(52) U.S. Cl. 250/226

(57) ABSTRACT

A photoelectric conversion apparatus includes a plurality of pixels, color filters disposed on a light-receiving surface of at least part of the plurality of pixels, infrared filters disposed on a light-receiving surface of the rest of the plurality of pixels, and a cutoff filter provided on the light-receiving surface of the plurality of pixels. Each pixel includes a photoelectric conversion element having photoelectric conversion sensitivity in a wavelength range including a visible light region and an infrared light region. Each color filter transmits visible light. Each infrared filter transmits infrared light. The cutoff filter shields light components in a wavelength range of approximately 650 nm to approximately 750 nm.

### CROSS-REFERENCE TO RELATED APPLICATIONS

This application claims priority to Japanese Patent Application No. 2006-137270, filed on May 17, 2006.

### BACKGROUND OF THE INVENTION

1. Field of the Invention

The present invention relates to a photoelectric conversion apparatus including a cutoff filter capable of shielding light with wavelengths in a near-infrared region.

2. Description of the Related Art

A camera is equipped with an image sensor or an image pickup element, such as a charge coupled device (CCD) or a complementary metal oxide semiconductor (C-MOS) . In general, the image pickup element includes a plurality of photoelectric conversion elements disposed in a two-dimensional pattern. Each photoelectric conversion element can convert incident light into an electric signal.

More specifically, a photoelectric conversion element formed on a silicon substrate has photoelectric conversion sensitivity in a visible light region (i.e., in a wavelength range of approximately 380 nm to approximately 700 nm) as well as in an infrared light region (i.e., in a wavelength range of approximately 700 nm to approximately 1100 nm).

Furthermore, to capture a color image of an object, the image pickup element includes RGB primary color filters or YMC complementary color filters disposed on a light-receiving surface of the photoelectric conversion elements. The color filters can separate incident light into a plurality of color components and convert the separated light components into electric signals in each wavelength range.

A photoelectric conversion apparatus can include a plurality of pixels with RGB primary color filters (or YMC complementary color filters) disposed on a light-receiving surface thereof, as well as a certain number of pixels with infrared filters disposed on a light-receiving surface thereof. The infrared filters are capable of transmitting light whose wavelength is in an infrared light (IR) region. As illustrated in a plan view of FIG. 7, the RGB primary color filters and the infrared filters are disposed in a mosaic pattern.

The photoelectric conversion apparatus can capture a color image based on visible light and infrared light. For example, in an outdoor shooting operation during daytime, the photoelectric conversion apparatus can obtain a color image based on subtraction between signals output from the pixels with color filters and signals output from the pixels with infrared filters. In a shooting operation in a dark room or during nighttime, the photoelectric conversion apparatus can obtain a color image based on signals output from the pixels with infrared filters and signals output from the pixels with color filters that can transmit infrared light.

FIG. 8 illustrates wavelength dependency with respect to sensitivity of a CCD image pickup element equipped with RGB primary color filters. In FIG. 8, an abscissa axis represents the wavelength (nm) of light and an ordinate axis represents relative transmissivity. As illustrated in FIG. 8, red, green, and blue color filters (refer to lines R, G, and B) can transmit light whose wavelength is in the infrared light region, which corresponds to a wavelength range exceeding 650 nm.

Accordingly, each pixel with a color filter generates an information charge including an electric charge generated by the light with wavelengths in the infrared light region. Thus, a color image includes noise components resulting from the charges generated by the light with wavelengths in the infrared light region. For example, as illustrated in FIG. 9, if certain vegetation reflects natural light, the reflected light includes many components of infrared light whose wavelength is equal to or greater than 650 nm. When the image pickup element captures a color image of this vegetation, both the pixels with red color filters and the pixels with blue color filters can generate information charges containing components resulting from infrared light.

If the photoelectric conversion apparatus forms a color image based on the signals output from the red, blue, and green pixels, the color image includes a large amount of noise components resulting from infrared light. As a result, the obtained color image of the vegetation cannot reproduce a natural green color.

The photoelectric conversion apparatus is required to enhance color reproducibility. To this end, in capturing a color image, it is required to remove any influence of infrared light components. However, as illustrated in FIG. 8, the light transmission characteristics of respective color filters are different from each other in a near-infrared region equivalent to a wavelength range of 650 nm to 800 nm.

If noise removal processing is uniformly applied to the signals output from respective color pixels, the processing cannot remove noise components resulting from the light components in the near-infrared region.

### SUMMARY OF THE INVENTION

The present invention is directed to a photoelectric conversion apparatus configured to receive incident light and generate an electric charge representing the intensity of the incident light.

According to an aspect of the present invention, a photoelectric conversion apparatus includes: a plurality of pixels each including a photoelectric conversion element having photoelectric conversion sensitivity in a wavelength range including a visible light region and an infrared light region; color filters disposed on a light-receiving surface of at least some of the plurality of pixels and configured to transmit both visible light and infrared light; infrared filters disposed on a light-receiving surface of the rest of the plurality of pixels and configured to transmit infrared light; and a cutoff filter provided on the light-receiving surface of the plurality of pixels and configured to shield light components in a wavelength range of approximately 650 nm to approximately 750 nm.

### BRIEF DESCRIPTION OF THE DRAWINGS

Exemplary embodiments of the present invention will be described in detail based on the following figures, wherein:

FIG. 1 is a block diagram illustrating a photoelectric conversion apparatus according to an exemplary embodiment of the present invention;

FIG. 2 is a plan view illustrating an exemplary arrangement of an image pickup section according to the exemplary embodiment of the present invention;

FIG. 3 is a cross-sectional view illustrating an exemplary arrangement of the image pickup section according to the exemplary embodiment of the present invention;

FIG. 4 is a cross-sectional view illustrating an exemplary arrangement of the image pickup section according to the exemplary embodiment of the present invention;

FIG. 5 illustrates wavelength dependency with respect to light transmissivity of the image pickup section according to the exemplary embodiment of the present invention;

FIG. 6 illustrates another exemplary arrangement of the photoelectric conversion apparatus according to the exemplary embodiment of the present invention;

FIG. 7 illustrates an exemplary layout of color filters;

FIG. 8 illustrates wavelength dependency with respect to sensitivity of an image pickup element (silicon substrate) equipped with general primary color filters;

FIG. 9 illustrates exemplary spectra of light reflected from certain vegetation; and

FIG. 10 illustrates an exemplary layout of infrared filters disposed along an outer periphery of the image pickup section.

### DESCRIPTION OF PREFERRED EMBODIMENTS

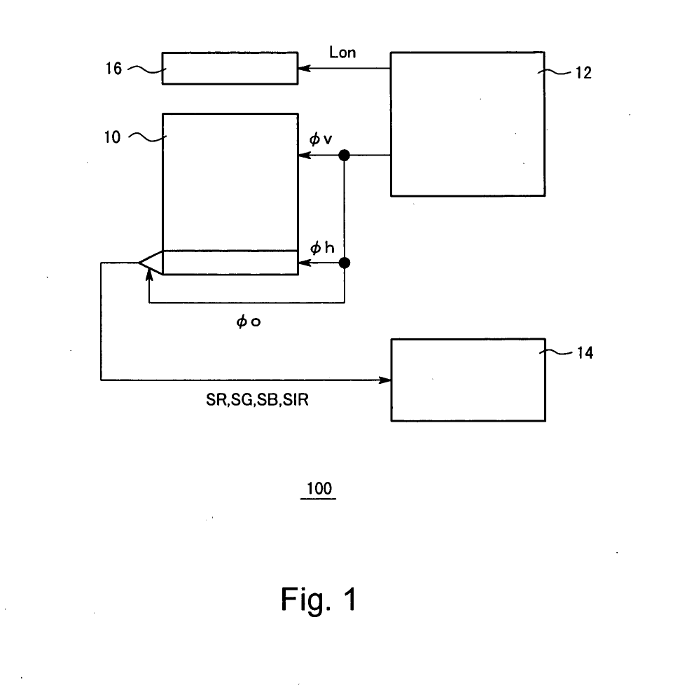

A photoelectric conversion apparatus 100 according to an embodiment of the present invention, as illustrated in FIG. 1, includes an image pickup section 10, a clock control section 12, a signal processing section 14, and an infrared light source 16. According to the photoelectric conversion apparatus 100 illustrated in FIG. 1, the image pickup section 10 generates an information charge based on incident light.

The clock control section 12 supplies clock signals (φv, φh, and φo) to the image pickup section 10. The image pickup section 10 transfers the information charge in response to a received clock signal. The image pickup section 10 can convert the information charge into electrical signals (SR, SG, SB, and SIR) and successively output the converted signals to the signal processing section 14. The signal processing section 14 applies noise removal processing to the input signals.

The photoelectric conversion apparatus 100 can capture a color image in an outdoor shooting operation during daytime or in a bright room and also can capture an infrared image in a shooting operation in a dark place or during nighttime.

When capturing an infrared image, the clock control section 12 outputs a light-on signal (Lon) to the infrared light source 16 in synchronism with shooting timing. The infrared light source 16 emits infrared light traveling toward an object. The image pickup section 10 forms an image of an object based on reflection light.

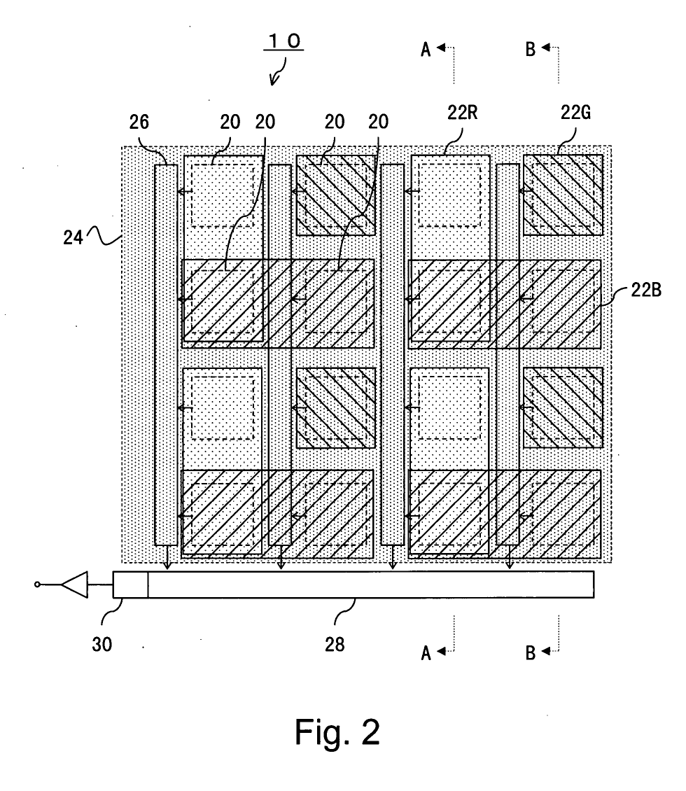

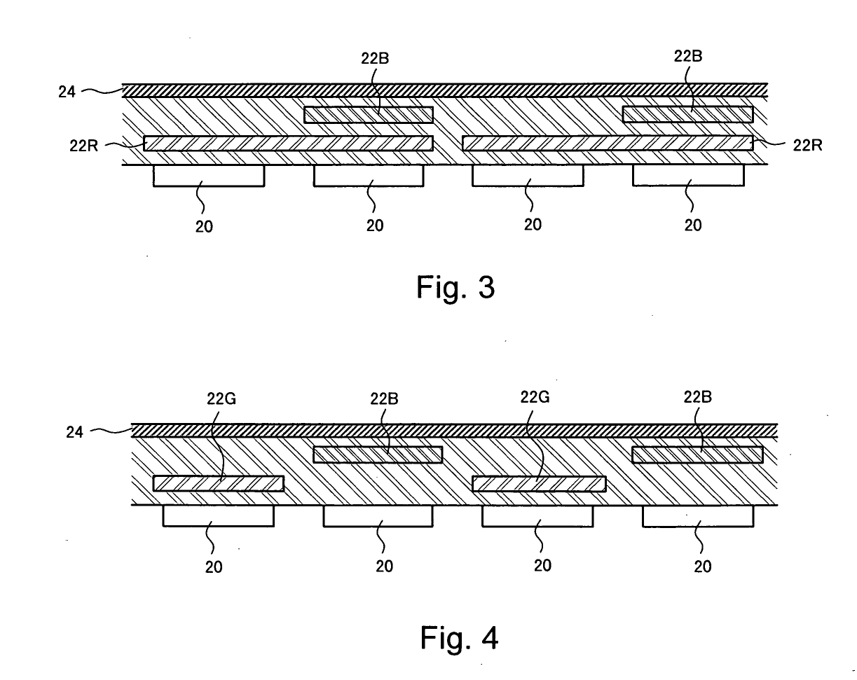

The image pickup section 10, as illustrated in a plan view of FIG. 2 and cross-sectional views of FIGS. 3 and 4, includes a plurality of photoelectric conversion elements 20, color filters 22R, 22G, and 22B, a near-infrared cutoff filter 24, vertical registers 26, a horizontal register 28 and an output section 30. FIG. 3 illustrates a cross-sectional view taken along a line A-A of FIG. 2. FIG. 4 illustrates a cross-sectional view taken along a line B-B of FIG. 2.

In the present embodiment, the image pickup section 10 includes a plurality of pixels disposed in a matrix pattern. Each pixel includes a photoelectric conversion element 20. The photoelectric conversion element 20 is, for example, a Si photo diode. The vertical registers 26 and the horizontal register 28 are charge coupled devices. The photoelectric conversion element 20, connected to the vertical register 26, generates an information charge. Each vertical register 26 transfers the information charge generated by an associated photoelectric conversion element 20 to the horizontal register 28 in a vertical direction (i.e., a downward direction in FIG. 2) in response to a clock signal (φv) supplied from the clock control section 12.

The horizontal register 28 transfers the information charge to the output section 30 in a horizontal direction (i.e., a leftward direction in FIG. 2) in response to a clock signal (Ph) supplied from the clock control section 12. The output section 30 converts the information charge into a voltage signal and successively outputs the converted signal to the signal processing section 14.

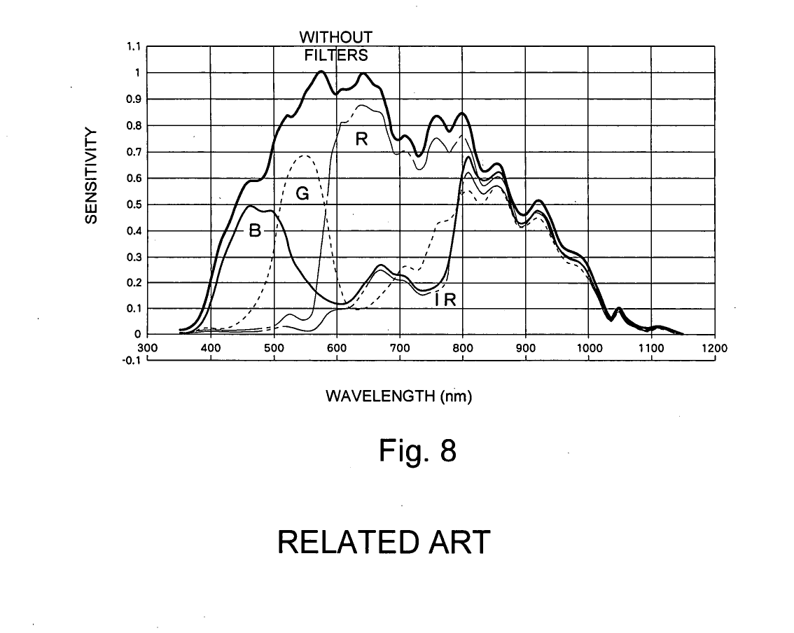

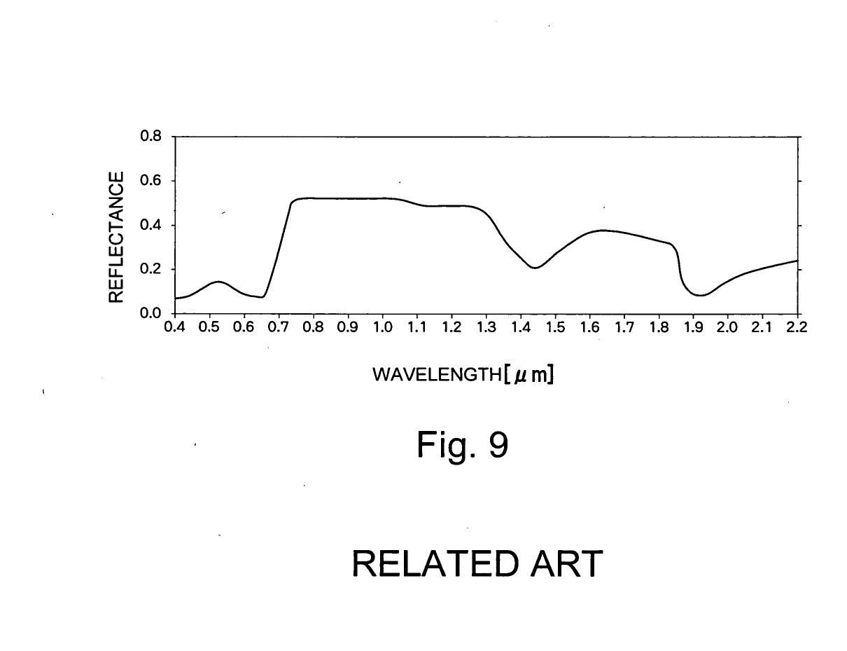

A total of four types of filters (i.e., a red color filter 22R, a green color filter 22G, a blue color filter 22B, and an infrared filter) are disposed on a light-receiving surface of the pixels disposed in a matrix pattern. The red color filter 22R transmits light whose wavelength is in a region corresponding to red color indicated by the line R in FIG. 8. The green color filter 22G transmits light whose wavelength is in a region corresponding to green color indicated by the line G in FIG. 8. The blue color filter 22B transmits light whose wavelength is in a region corresponding to blue color indicated by the line B in FIG. 8. The infrared filter, arranged by a lamination of the red color filter 22R and the blue color filter 22B, transmits light whose wavelength is in an infrared region.

Thus, the image pickup section 10 includes a plurality of pixels with four different filters having mutually different transmission characteristics and disposed in a mosaic pattern. In this embodiment, the “mosaic pattern” represents a random layout of different filters disposed in a two-dimensional pattern.

The red color filter 22R has light transmissivity gradually decreasing when the wavelength changes from approximately 350 nm to approximately 420 nm. The red color filter 22R can shield almost all light components in a wavelength region of approximately 420 nm to approximately 500 nm. Thetransmissivity of the red color filter 22R gradually increases after the wavelength exceeds approximately 500 nm. The red color filter 22R can transmit, at a higher rate, the light whose wavelength is equal to or greater than approximately 550 nm.

The green color filter 22G can shield visible light components in a wavelength range of approximately 360 nm to approximately 420 nm. The transmissivity of the green color filter 22G gradually increases when the wavelength exceeds approximately 420 nm and has a peak at the wavelength equal to approximately 520 nm corresponding to green color. The transmissivity of the green color filter 22G gradually decreases until the wavelength reaches approximately 650 nm and gradually increases after the wavelength exceeds approximately 650 nm. The green color filter 22G can transmit, at a higher rate, infrared light whose wavelength is equal to or greater than approximately 880 nm.

The blue color filter 22B has light transmissivity that increases after the wavelength exceeds approximately 380 nm and has a peak at the wavelength equal to approximately 460 nm corresponding to blue color. The transmissivityof the blue color filter 22B decreases until the wavelength reaches approximately 580 nm and gradually increases after the wavelength exceeds approximately 620 nm. The transmissivity of the blue color filter 22B has a small peak at approximately 690 nm. The blue color filter 22B can transmit, at a higher rate, infrared light whose wavelength is equal to or greater than approximately 800 nm.

The photoelectric conversion element 20 has sensitivity maximized at the wavelength equal to approximately 500 nm. The photoelectric conversion element 20 has sensitivity in a wide range including the visible light region and the infrared region (i.e., in a wavelength region ranging beyond 780 nm and reaching approximately 1100 nm).

In the present embodiment, as illustrated in FIGS. 2 and 3, the red color filter 22R and the blue color filter 22B are laminated to form an infrared filter. According to an exemplary structure of the infrared filter, the red color filter 22R extends from a pixel on which only a red color filter 22R is provided to a pixel on which an infrared filter is provided. The blue color filter 22B extends from a pixel on which only a blue color filter 22B is provided to a pixel on which an infrared filter is provided. According to the arrangement illustrated in FIGS. 2 and 3, the infrared filter can be formed together with the red color filter 22R and the blue color filter 22B in the same manufacturing process.

The infrared filter, as indicated by a line IR in FIG. 8, substantially shields visible light whose wavelength is equal to or less than approximately 580 nm. The transmissivity of the infrared filter gradually increases after the wavelength exceeds approximately 580 nm. The infrared filter and the blue color filter 22B have similar transmission characteristics in a wavelength range exceeding approximately 690 nm.

In the present embodiment, the near-infrared cutoff filter 24 is disposed on the light-receiving surface of the pixels. The near-infrared cutoff filter 24 can shield light components with wavelengths in a near-infrared region. More specifically, it is useful that the near-infrared cutoff filter 24 has filtering characteristics capable of shielding light whose wavelength is in a wavelength range of approximately 650 nm to approximately 750 nm. More specifically, it is preferable that the near-infrared cutoff filter 24 has filtering characteristics capable of shielding light whose wavelength is shorter than a wavelength range of the light emitted from the infrared light source 16.

For example, if the infrared light source 16 emits light having a peak intensity at the wavelength equal to 850 nm and the infrared light source 16 has a wavelength dispersion of ±50 nm, it is preferable that the near-infrared cutoff filter 24 has filtering characteristics capable of shielding light whose wavelength is in a range of approximately 650 nm to approximately 800 nm.

Furthermore, if the infrared light source 16 emits light having a peak intensity at the wavelength equal to 900 nm and the infrared light source 16 has a wavelength dispersion of ±50 nm, it is preferable that the near-infrared cutoff filter 24 has filtering characteristics capable of shielding light whose wavelength is in a range of approximately 650 nm to approximately 850 nm.

A pixel with a red color filter 22R provided thereon has a distribution of sensitivity, which has a peak at the wavelength equal to approximately 600 nm corresponding to red color and extends widely from the visible light region into the infrared region.

A pixel with a green color filter 22G provided therein has a distribution of sensitivity, which has a peak at the wavelength equal to approximately 520 nm corresponding to green color and extends widely from the visible light region into the infrared light region.

A pixel with a blue color filter 22B provided thereon has a distribution of sensitivity, which has a peak at the wavelength equal to approximately 460 nm corresponding to blue color and extends widely from the visible light region into the infrared light region.

A pixel with an infrared filter provided thereon has no sensitivity to visible light because the red color filter 22R and the blue color filter 22B are laminated on a light-receiving surface of the pixels. The infrared filter has a distribution of sensitivity ranging from the near-infrared region (exceeding 650 nm) to the infrared region.

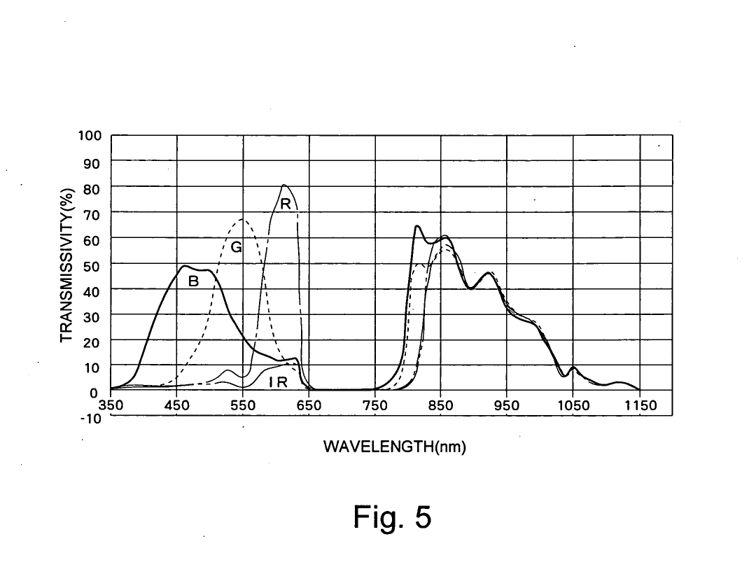

The image pickup section 10 according to the present embodiment has the near-infrared cutoff filter 24 configured to shield the light whose wavelength is in the near-infrared region. Therefore, the color signals SR, SG, and SB output from the pixels with the color filters 22R, 22G, and 22B include no noise components resulting from the light components in the cutoff region of the near-infrared cutoff filter, as shown in FIG. 5.

However, the signals SR, SG, and SB output from the image pickup section 10 still include noise components (charge) generated by the light components in the infrared region. Accordingly, if these signals SR, SG, and SB are directly used, the photoelectric conversion apparatus cannot form a color image having accurate color reproducibility.

Hence, the signal processing section 14 performs predetermined processing for removing the noise components in the infrared light region to obtain corrected color signals SR, SG, and SB, based on an output signal SIR obtained from the pixels with the infrared filters provided thereon.

With the above-described noise removal processing, the photoelectric conversion apparatus can remove noise components outside the visible light region and can form a color image having excellent color reproducibility.

More specifically, as exemplary processing for removing infrared light components from the color signals, the signal processing section 14 can subtract the signal SIR from each of the output signals SR, SG, and SB. In this case, the signal processing section 14 can equally and properly remove the noise components from the primary color signals because the near-infrared cutoff filter 24 can remove the light components in the near-infrared region (in particular, in a wavelength range of 650 nm to 750 nm) in which the sensitivity is different for each color. Thus, the signal processing section 14 can realize accurate color reproducibility for each of three primary color signals.

Furthermore, the signal processing section 14 can perform white balance adjustment processing for the color signals. For example, the signal processing section 14 can adjust the gains for the red color signal SR and the blue color signal SB relative to the gain for the green color signal SG based on the infrared signal SIR.

For example, as an exemplary white balance adjustment for the color signals, the signal processing section 14 can decrease the gain for the red color signal SR by a predetermined amount and increase the gain for the blue color signal SB by a predetermined amount, if the infrared signal SIR is greater than a predetermined signal amount.

On the other hand, if the infrared signal SIR is smaller than the predetermined signal amount, the signal processing section 14 can equally control the gains for the red color signal SR and the blue color signal SB.

In the above-described embodiment, the image pickup section 10 can be constituted by a CCD. An exemplary embodiment for transferring electric charges can be realized by a CCD of a frame transfer (FT) type, an interline transfer (IT) type, or a frame interline transfer (FIT) type. Furthermore, the photoelectric conversion element 20 according to the present embodiment can be constituted by a CMOS image sensor.

According to image pickup section 10 according to the present embodiment, both the red color filter 22R and the blue color filter 22B are included in each photoelectric conversion element block consisting of four photoelectric conversion elements 20. However, the red color filters 22R can be continuously arrayed straight along a column while the blue color filters 22B can be continuously arrayed straight along a row of the photoelectric conversion elements 20 disposed in a two-dimensional pattern.

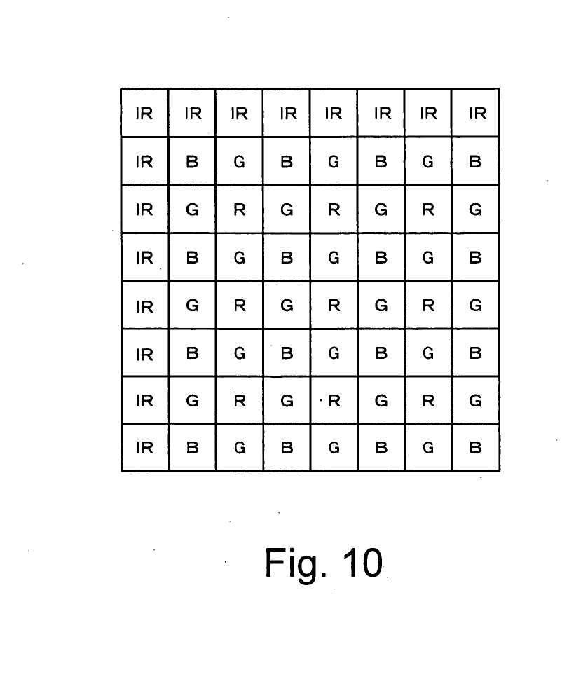

Furthermore, as illustrated in FIG. 10, pixels with the infrared filters provided thereon can be disposed along an outer periphery of an image pickup region that is constituted by numerous pixels with color filters provided thereon.

The arrangement illustrated in FIG. 10 can realize a precise layout of photoelectric conversion elements that convert visible light components and infrared light components into electric signals, and can attain high resolution in an image pickup operation.

Furthermore, the arrangement illustrated in FIG. 10 can detect infrared light components of an object and can selectively output an infrared light signal which is used to correct infrared light components. Thus, the arrangement illustrated in FIG. 10 can realize accurate color reproducibility.

Furthermore, according to the above-described embodiment of the present invention, the image pickup section 10 is comprised of a combination of the red, blue, and green color filters 22R, 22G, and 22B. However, the image pickup section 10 can be formed by a combination of yellow (Ye), magenta (Mg), and cyan (Cy) color filters, a combination of yellow (Ye), cyan (Cy) and green (G) color filters, or a combination of yellow (Ye), cyan (Cy), magenta (Mg), and green (G) color filters. In other words, according to the present embodiment, the image pickup section 10 can be constituted by combining primary color filters or by combining complementary color filters.

For example, the red color filters 22R, the blue color filters 22B, and the green color filters 22G disposed on the light-receiving surface of the photoelectric conversion elements are replaced with yellow, magenta, and cyan color filters. In this case, an exemplary layout of the filters is a sequential color-difference complementary color diced pattern or a complementary color diced pattern.

At least two types of plural color filters are capable of transmitting infrared light. The infrared filter is arranged by laminating the color filters capable of transmitting infrared light which are selected from the plurality of types of color filters.

More specifically, an infrared filter capable of exclusively transmitting infrared light can be arranged by laminating yellow, magenta, and cyan color filters. If the above-described infrared filter is disposed on a light-receiving surface of a pixel, the pixel is non-sensitive to almost all visible light components and has higher sensitivity against infrared light whose wavelength is equal to or greater than approximately 650 nm.

The above-described color image pickup element requires no infrared light transmission filters provided separately. Accordingly, the color image pickup element according to the present embodiment can be fabricated at a low cost and exhibits excellent sensitivity. Even in a case where the complementary color filters are used, the near-infrared cutoff filter 24 is provided on the light-receiving surface of the image pickup section 10. It is preferable that the near-infrared cutoff filter 24 can shield light whose wavelength is in a range of approximately 650 nm to approximately 750 nm.

The color signals SYe, SMg, and SCy (or SYe, SMg, SCy, and SG) output from the image pickup section 10 still include noise components (charge) resulting from the light components in the infrared region. Accordingly, if these signals SYe, SMg, and SCy (or SYe, SMg, SCy, and SG) are used directly, the photoelectric conversion apparatus cannot form a color image having accurate color reproducibility.

Hence, the signal processing section 14 performs processing for removing infrared light components from output signals SYe, SMg, and SCy (or SYe, SMg, SCy, and SG) based the output signal SIR obtained from the pixels with the infrared filters provided thereon.

More specifically, as exemplary processing for removing infrared light components from the complementary color signals, the signal processing section 14 can subtract the signal SIR from each of the output signals SYe, SMg, and SCy (or SYe, SMg, SCy, and SG). In this case, the signal processing section 14 can equally and properly remove the noise components from the complementary color signals because the near-infrared cutoff filter 24 can remove the light components in the near-infrared region (in particular, in a wavelength range of 650 nm to 750 nm) in which the sensitivity is different for each color. Thus, the signal processing section 14 can realize accurate color reproducibility for each of the complementary color signals.

As described above, the present invention can be applied to any filter arrangement that can separate incident light into complementary color signals. Thus, the present invention is not limited to the above-described filter arrangement for the image pickup section 10 that separates incident light into red, green, and blue color signals.

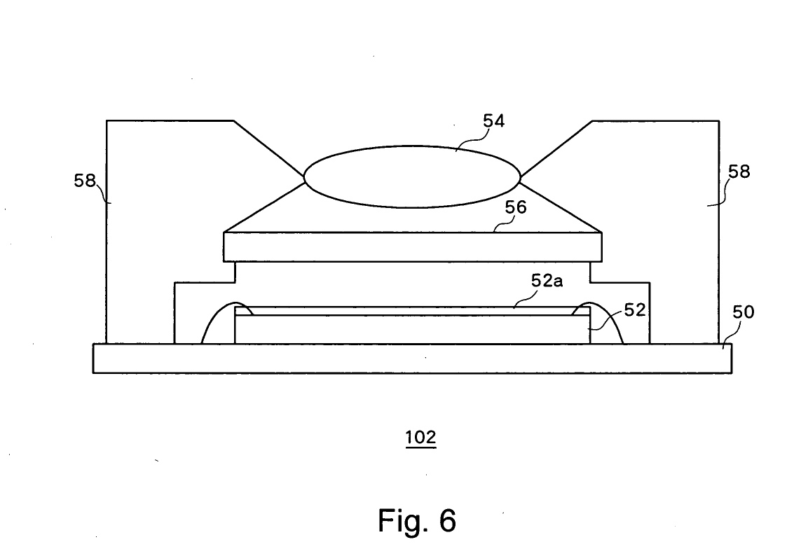

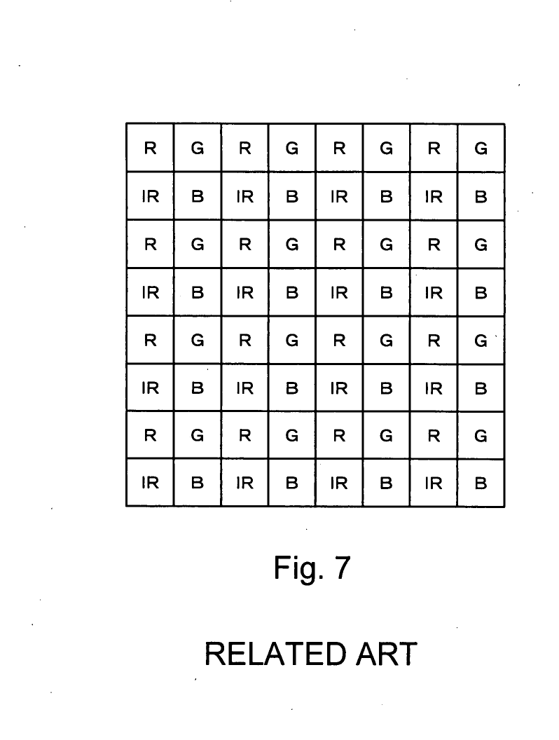

Furthermore, the present embodiment is not structurally limited to the above-described image pickup section 10 that includes the near-infrared cutoff filter 24. For example, a modified embodiment of the present invention may include a camera module 102 illustrated in a cross-sectional view of FIG. 6. According to the embodiment illustrated in FIG. 6, a substrate 50 and an image pickup element 52 with a color filter 52a provided on its image pickup surface form an image pickup apparatus. A near-infrared cutoff filter 56 is disposed between a collective lens 54 and the image pickup element 52. The near-infrared cutoff filter 56 can be supported by a lens holder 58 that supports a collective lens 54.

What is claimed is:

1. A photoelectric conversion apparatus configured to receive incident light and generates an electric charge representing the intensity of the incident light, comprising:
a plurality of pixels each including a photoelectric conversion element having photoelectric conversion sensitivity in a wavelength range including a visible light region and an infrared light region;
color filters disposed on a light-receiving surface of at least some of the plurality of pixels and configured to transmit both visible light and infrared light;
infrared filters disposed on a light-receiving surface of the rest of the plurality of pixels and configured to transmit infrared light; and
a cutoff filter provided above the light-receiving surface of the plurality of pixels and configured to shield light components in a wavelength range of approximately 650 nm to approximately 750 nm

2. The photoelectric conversion apparatus according to claim 1, wherein the color filters are 3-color filters based on a combination of red, green, and blue, a combination of yellow, cyan, and magenta, or a combination of yellow, cyan, and green, or 4-color filters based on a combination of yellow, cyan, magenta, and green.

3. The photoelectric conversion apparatus according to claim 1, wherein at least two types of the color filters are configured to transmit light components in the infrared light region, and are laminated to form the infrared filters.

4. The photoelectric conversion apparatus according to claim 2, wherein at least two types of the color filters are configured to transmit light components in the infrared light region, and are laminated to form the infrared filters.

5. The photoelectric conversion apparatus according to claim 3, wherein a red color filter and a blue color filter are laminated to form an infrared filter.

6. The photoelectric conversion apparatus according to claim 4, wherein a red color filter and a blue color filter are laminated to form an infrared filter.

7. The photoelectric conversion apparatus according to claim 3, wherein a yellow color filter, a cyan color filter, and a magenta color filter are laminated to form an infrared filter.

8. The photoelectric conversion apparatus according to claim 4, wherein a yellow color filter, a cyan color filter, and a magenta color filter are laminated to form an infrared filter.

9. The photoelectric conversion apparatus according to claim 1, wherein a signal output from a pixel with the color filter disposed on the light-receiving surface thereof is corrected based on a signal output from a pixel with the infrared filter disposed on the light-receiving surface thereof.

10. The photoelectric conversion apparatus according to claim 2, wherein a signal output from a pixel with the color filter disposed on the light-receiving surface thereof is corrected based on a signal output from a pixel with the infrared filter disposed on the light-receiving surface thereof.

11. The photoelectric conversion apparatus according to claim 3, wherein a signal output from a pixel with the color filter disposed on the light-receiving surface thereof is corrected based on a signal output from a pixel with the infrared filter disposed on the light-receiving surface thereof.
